(19) United States
(12) Patent Application Publication
(10) Pub. No.: US 2026/0221722 A1
(43) Pub. Date: Jul. 30, 2026

(54) SURFACE EMITTING LASER DEVICES AND METHODS FOR MANUFACTURING SAME

(71) Applicant: VECTOR PHOTONICS LIMITED, Glasgow (GB)

(72) Inventors: Richard TAYLOR, Glasgow (GB); David CHILDS, Glasgow (GB); Richard HOGG, SouthYorkshire (GB)

(21) Appl. No.: 19/141,506

(22) PCT Filed: Dec. 13, 2023
(86) PCT No.: PCT/GB2023/053222

§ 371 Date: Jun. 20, 2025

(30) Foreign Application Priority Data
Dec. 21, 2022 (GB) 2219452.6

(51) Int. Cl. H01S 5/11; H01S 5/042; H01S 5/183

(52) U.S. Cl. CPC H01S 5/11; H01S 5/0421; H01S 5/18394

(57) ABSTRACT

A surface emitting laser device and a method for manufacturing is disclosed. The surface emitting laser device comprises a p-type semiconductor substrate on which are formed a photonic crystal (PC) structure comprising a bulk medium having a first refractive index and an array of scattering centres located within the bulk medium, the scattering centres having a second refractive index different to the first refractive index; and an active layer, optically coupled to the photonic crystal structure. The described surface emitting laser device is found to exhibit lower gain threshold values, improved L-I slope efficiency and higher output powers than that those known in the art which are formed on a p-type semiconductor substrate.

The present invention relates to the field of surface emitting laser devices and methods for manufacturing these devices. In particular, the present invention relates to photonic crystal surface emitting laser (PCSEL) devices and methods for manufacturing the same.

Semiconductor laser devices are solid-state lasers based on semiconductor gain media, where optical amplification is usually achieved through stimulated recombination of charge carriers. Most semiconductor laser devices are laser diodes based on a semiconductor gain media, which is pumped with an electrical current in a region where n-doped and p-doped semiconductor materials meet. As the photon energy of a laser diode is close to the bandgap energy, compositions with different bandgap energies allow for different emission wavelengths.

Photonic crystal surface emitting lasers (PCSELs) are one class of semiconductor laser device. PCSELs have been found to have beneficial properties including coherent oscillation, and low divergences of emitted light. PCSELs are also the only semiconductor laser design that employs two dimensional in-plane feedback and out of plane, surface emission.

PCSELs can be made from a number of different semiconductor materials. An example PCSEL structure as known in the art, and generally depicted by reference numeral 1, is presented in FIG. 1. In particular, FIG. 1 presents a cross sectional view of the PCSEL 1.

The PCSEL 1 can be seen to comprise an n-type semiconductor substrate 2 upon which the other layers of the PCSEL 1 are formed. Example n-type semiconductor substrates include Indium Phosphide (InP) doped with Tin or Sulphur, or Gallium Arsenide (GaAs) doped with Tin, Sulphur or Indium.

Traditionally, n-type semiconductor substrates are preferred to p-type semiconductor substrates as a starting point for producing a semiconductor laser device. The reasons for this include the fact that p-type semiconductor substrates exhibit free carrier cross sectional losses that are significantly higher than for similar sized and doped n-type semiconductor substrates. In addition, n-type semiconductor substrates generally exhibit lower defect densities (also known as etch pit density (EPD)) when compared to p-type semiconductor substrates. Furthermore, p-type dopants, such as Zinc or Beryllium, are more diffusive and thus prone to surface segregation. Without further controls being incorporated into the semiconductor laser device, these diffusive dopants can propagate into the active zone and thus degrade the properties of the laser device. For the above reasons semiconductor laser devices grown on n-type semiconductor substrates are generally found to be of better quality and of higher reliability than those grown on p-type semiconductor substrates.

The subsequently described layers that make up the PCSEL 1 are grown on the n-type semiconductor substrate 2 by one or more of a number of techniques known in the art, for example metal-organic vapor phase epitaxy (MOVPE) techniques; metal-organic chemical vapour deposition (MOCVD) techniques and molecular beam epitaxy (MBE) techniques.

The PCSEL 1 can be seen to further comprise a multi-quantum well (MQW) active layer 3 of a type well known in the art. On opposite sides of the MQW active layer 3 are located first 4 and second 5 layers of an undoped semiconductor material. The refractive indices of layers 4 and 5 are selected to be lower than the refractive index of the MQW active layer 3. As such, layers 4 and 5 are employed as separate confinement heterostructure (SCH) layers within the PCSEL 1 and thus assists with the confinement of light within the MQW active layer 3.

Located between the first SCH layer 4 and the n-type semiconductor substrate 2 is a first 6 and a second n-type semiconductor layer 7. The function of the first n-type semiconductor layer 6 is to act as a first cladding layer within the PCSEL 1. The thickness and doping levels within the second n-type semiconductor layer 7 are selected depending on the output light requirements of the PCSEL 1.

On the opposite side of the MQW active layer 3, to that on which the n-type semiconductor substrate 2 is located, there is provided a first p-type semiconductor layer 8, the function of which is to act as a second cladding layer within the PCSEL 1 device. There is then provided a second layer of a p-type semiconductor material 9 into which a two-dimensional array of atoms or voids 10 is etched such that this layer acts as a photonic crystal (PC) layer 9 within the PCSEL 1 device. Optionally, a third layer of a p-type semiconductor material 11 is then overgrown on the p-type semiconductor material 9 such that the array of atoms 10 is infilled with the third layer of p-type semiconductor material 11, thus effectively forming a p-type grating structure within the PCSEL 1. In the absence of p-type semiconductor material 11 the array of atoms 10 are air filled. The final semiconductor layer of the PCSEL 1 is a fourth layer of a p-type semiconductor material 12 the thickness and doping levels within which are selected depending on the output light requirements of the PCSEL 1.

Electrical contacts 13 and 14 are located on the external surfaces of the PCSEL 1. The second electrical contact 14 is in the shape of a ring, the aperture of which defines the output surface 15 of the PCSEL 1. As a result of the above described structure, when an electrical current is provided between the first 13 and second 14 electrical contacts, the PCSEL 1 begins to lase and an output field 16 is emitted from the output surface 15.

The slope efficiency

$$( \frac{dP}{dI} )$$

and threshold gain (gₜₕ) of the PCSEL 1 are defined by equations (1) and (2) below:

$$\frac{dP}{dI} = \frac{hv}{e} {η}_{i} ( {α}_{⊥} ) / ( {α}_{⊥} + {α}_{//} + {α}_{i} ) {η}_{up} \qquad ( 1 )$$

$${g}_{th} = {α}_{⊥} + {α}_{//} + {α}_{i} \qquad ( 2 )$$

where
h is Planck's constant;
v is the frequency of the emitted light;
α_{⊥} is the radiative out-of-plane loss;
α_{//} is the in-plane parasitic loss of modal optical power;
αᵢ is the internal loss e.g. loss of modal optical power through parasitic absorption, scattering from roughness;
ηᵢ is the internal efficiency (conversion of current to lasing mode photons); and
ηᵤₚ is the fraction of light scattered out of plane that is emitted.

### Summary of Invention

It is therefore an object of an embodiment of the present invention to provide an alternative photonic crystal surface emitting laser (PCSEL) device to those known in the art.

It is a further object of an embodiment of the present invention to provide a photonic crystal surface emitting laser (PCSEL) device that exhibits improved operating parameters when comparted with those PCSELs known in the art. These improved operating parameters may include one or more of threshold current, L-I slope efficiency and output powers.

According to a first aspect of the present invention there is provided a surface emitting laser device comprising a p-type semiconductor substrate on which are formed:
a photonic crystal structure comprising a bulk medium having a first refractive index and an array of scattering centres located within the bulk medium, the scattering centres having a second refractive index different to the first refractive index;
an active layer, optically coupled to the photonic crystal structure;
an n-type semiconductor layer,
   wherein the n-type semiconductor layer is formed on the p-type semiconductor substrate after the photonic crystal structure and active layer are formed.

The term “formed” relates to the formation of layers of the surface emitting laser device, for example by sequential employment of semiconductor depositing and or growing techniques known in the art. As will be appreciated by the skilled reader, there is no requirement for a formed layer to be in direct contact with the p-type semiconductor substrate but instead when a new layer is formed on the p-type semiconductor substrate there may be one or more previously formed layers located between the p-type semiconductor substrate and the newly formed layer.

The above surface emitting laser device formed on a p-type semiconductor substrate is found to exhibit lower gain threshold values, improved L-I slope efficiency and higher output powers than that those known in the art which are formed on a p-type semiconductor substrate.

Preferably the photonic crystal structure is located between the active layer and the p-type semiconductor substrate. With this arrangement, the risk of damaging the active layer when forming the photonic crystal structure is removed.

The p-type semiconductor substrate may comprise Indium Phosphide (InP) or Gallium Arsenide (GaAs). The p-type semiconductor substrate may comprise a Zinc or Beryllium dopant material.

Preferably the bulk medium comprises a first n-type semiconductor material. Optionally the first n-type semiconductor material comprises Indium Gallium Arsenide Phosphide (InGaAsP) and a Tin, Sulphur or Indium dopant material. Preferably the scattering centres comprise atoms or voids formed within the bulk medium.

Most preferably the atoms or voids are infilled with a second n-type semiconductor material. Optionally the second n-type semiconductor material comprises Indium Phosphide (InP) and a Tin, Sulphur or Indium dopant material.

Preferably the active layer comprises a Multi-Quantum Well (MQW) active layer.

Preferably the surface emitting laser device further comprises a p-type semiconductor layer located between the active layer and the p-type semiconductor substrate. Preferably the surface emitting laser device further comprises an n-type semiconductor layer located on the opposite side of the active layer to that of the p-type semiconductor layer.

The surface emitting laser device may further comprise first and second cladding layers located on opposite sides of the active layer. Most preferably the first and second cladding layers comprise first and second graded cladding layers. The incorporation of graded cladding layers is found to provide for better electrical conduction through the surface emitting laser device and for better optical confinement within the active layer.

Optionally the surface emitting laser device further comprises a first separate confinement heterostructure (SCH) layer located between the first cladding layer and the active layer.

Optionally the surface emitting laser device further comprises a second separate confinement heterostructure (SCH) layer located between the second cladding layer and the active layer.

The surface emitting laser device optionally further comprises a first and second electrical contact located on opposite external surfaces of the device. Most preferably the first or second electrical contacts comprise an aperture which defines the output surface of the surface emitting laser device.

According to a second aspect of the present invention there is provided method of manufacturing a surface emitting laser device comprising a p-type semiconductor substrate, the method comprising forming on the p-type semiconductor substrate:
a photonic crystal structure comprising a bulk medium having a first refractive index and an array of scattering centres located within the bulk medium, the scattering centres having a second refractive index different to the first refractive index;
an active layer, optically coupled to the photonic crystal structure; and
an n-type semiconductor layer
   wherein the n-type semiconductor layer is formed on the p-type semiconductor substrate after the photonic crystal structure and active layer are formed.

Preferably the photonic crystal structure is formed on the p-type semiconductor substrate before the active layer.

Forming the photonic crystal on the p-type semiconductor substrate may comprise depositing a layer of a first n-type semiconductor material to form the bulk medium.

Forming the photonic crystal on the p-type semiconductor substrate may further comprise etching a plurality of atoms or voids within the layer of the first n-type semiconductor material to form the array of scattering centres.

Most preferably forming the photonic crystal on the p-type semiconductor substrate further comprises depositing a layer of a second n-type semiconductor material to infill the plurality of atoms or voids.

The method of manufacturing a surface emitting laser device may further comprise comprising forming a p-type semiconductor layer between the active layer and the p-type semiconductor substrate. Preferably the method of manufacturing a surface emitting laser device may further comprise forming an n-type semiconductor layer located on the opposite side of the active layer to that of the p-type semiconductor layer.

Preferably the method of manufacturing a surface emitting laser device further comprises forming first and second cladding layers located on opposite sides of the active layer. Most preferably forming the first and second cladding layers comprised forming first and second graded cladding layers.

Preferably the method of manufacturing a surface emitting laser device further comprises forming a first separate confinement heterostructure (SCH) layer located between the first cladding layer and the active layer.

Preferably the method of manufacturing a surface emitting laser device further comprises forming a second separate confinement heterostructure (SCH) layer located between the second cladding layer and the active layer.

Most preferably the method of manufacturing a surface emitting laser device further comprises providing a first and a second electrical contact located on opposite external surfaces of the device.

Most preferably providing the first and second electrical contacts comprises providing an aperture within the first or second electrical contacts to define an output surface of the surface emitting laser device.

Embodiments of the second aspect of the present invention may comprise features to implement the preferred or optional features of the first aspect of the present invention or vice versa.

According to a third aspect of the present invention there is provided a surface emitting laser device comprising:
a semiconductor substrate on which are located
   a photonic crystal structure comprising a bulk medium having a first refractive index and an array of scattering centres located within the bulk medium, the scattering centres having a second refractive index different to the first refractive index; and
   an active layer, optically coupled to the photonic crystal structure
wherein the semiconductor substrate comprises a p-type semiconductor substrate.

Embodiments of the third aspect of the present invention may comprise features to implement the preferred or optional features of the first or second aspects of the present invention or vice versa.

According to a fourth aspect of the present invention there is provided method of manufacturing a surface emitting laser device the method comprising:
providing a semiconductor substrate; and
forming on the semiconductor substrate
   a photonic crystal structure comprising a bulk medium having a first refractive index and an array of scattering centres located within the bulk medium, the scattering centres having a second refractive index different to the first refractive index; and
   an active layer, optically coupled to the photonic crystal structure
   wherein providing the semiconductor substrate comprises providing a p-type semiconductor substrate.

Embodiments of the fourth aspect of the present invention may comprise features to implement the preferred or optional features of the first, second or third aspects of the present invention or vice versa.

### BRIEF DESCRIPTION OF DRAWINGS

There will now be described, by way of example only, various embodiments of the invention with reference to the drawings, of which:

FIG. 1 presents a cross sectional view, of a photonic crystal surface emitting laser (PCSEL) as known in the art;

FIG. 2 presents theoretical modelling results of the PCSEL of FIG. 1 showing a normalised vertical optical mode profile overlaid upon the PCSEL, and highlighting the p-type region of the device;

FIG. 3 presents theoretical modelling results of the PCSEL of FIG. 1 showing a normalised vertical optical mode profile overlaid upon the PCSEL, and highlighting the n-type region of the device;

FIG. 4 presents a cross sectional view, of a photonic crystal surface emitting laser (PCSEL) in accordance with an embodiment of the present invention;

FIG. 5 presents a cross sectional view, of a photonic crystal surface emitting laser (PCSEL) in accordance with an alternative embodiment of the present invention;

FIG. 6 presents a cross sectional view, of a photonic crystal surface emitting laser (PCSEL) in accordance with a further alternative embodiment of the present invention; and

FIG. 7 presents a cross sectional view, of a photonic crystal surface emitting laser (PCSEL) in accordance with a yet further alternative embodiment of the present invention.

In the description which follows, like parts are marked throughout the specification and drawings with the same reference numerals. The drawings are not necessarily to scale and the proportions of certain parts have been exaggerated to better illustrate details and features of embodiments of the invention.

### DETAILED DESCRIPTION

In a photonic crystal surface emitting laser (PCSEL) it is the photonic crystal (PC) which provides the necessary feedback for lasing to take place. This feedback is produced as a result of the bulk medium from which the photon crystal (PC) is produced exhibiting a first refractive index which differs from the refractive index of the infilled or air-filled array of atoms which therefore act as scattering centres within the photon crystal (PC). It is therefore crucial that the design of the PCSEL structure produces a high overlap of the vertical optical mode with the photonic crystal if a high power per unit area is to be obtained. Much effort is therefore given to theoretical modelling of PCSEL structures to help understand what aspects of the structure have the most significant impact on the overlap of the vertical optical mode with the photonic crystal, MQW active layer and the lossy cladding layers.

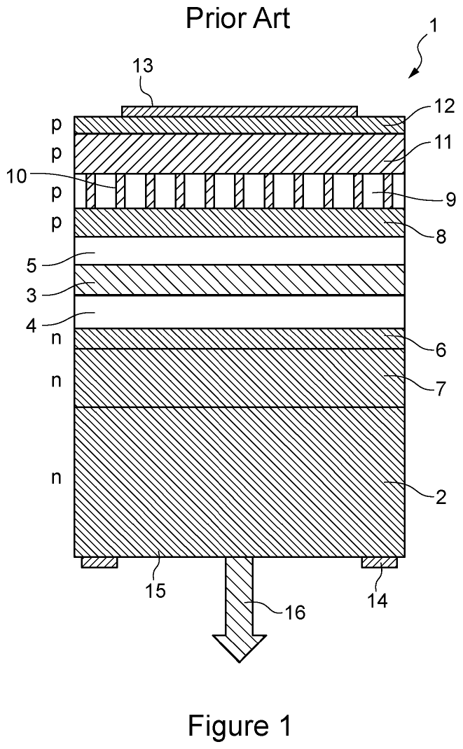

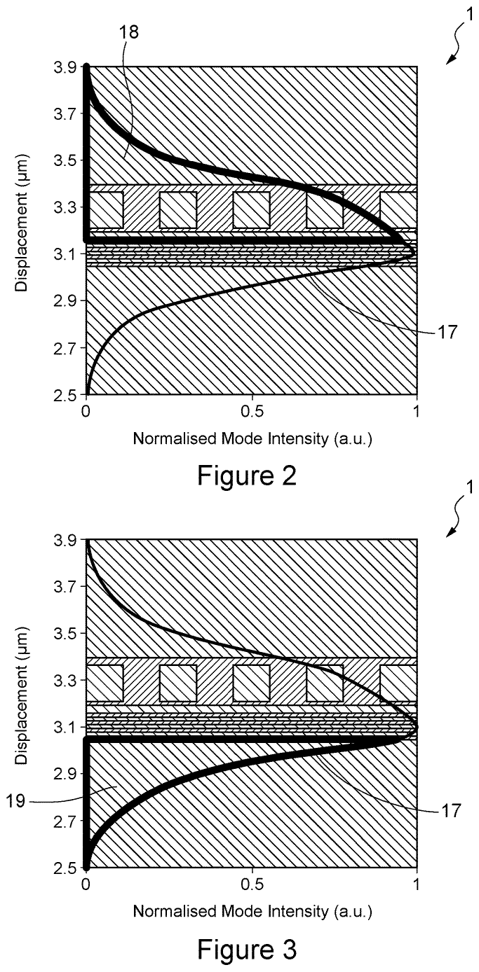

By way of example, FIGS. 2 and 3 present modelled, normalised vertical optical mode profiles 17 overlaid upon a PCSEL 1 of the type presented within FIG. 1. In particular, in FIG. 2 the area 18 outlined with the thick line corresponds to the overlap of the normalised vertical optical mode profile 17 and the p-type region of the PCSEL 1. By contrast, in FIG. 3 the area 19 outlined with the thick line corresponds to the overlap of the normalised vertical optical mode profile 17 and the n-type region of the PCSEL 1. From an analysis of these results it was recognised by the applicants that the overlap of the normalised vertical optical mode profile 17 within the p-type region 18 of the PCSEL 1 is around three times greater than that of the normalised vertical optical mode profile within the n-type region 19 of the PCSEL 1. When combined with the known greater free carrier cross sectional losses, the overall result is that losses within the p-type region 18 of the PCSEL 1 are around twenty times higher than those within the n-type region 19.

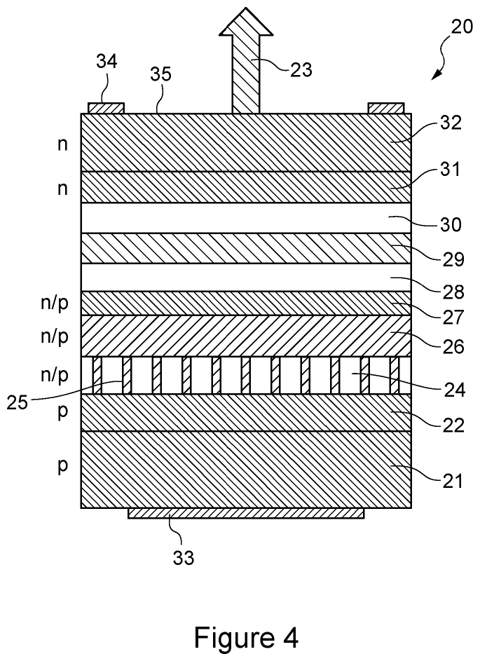

A photonic crystal surface emitting laser (PCSEL) 20 in accordance with an embodiment of the present invention, and its method of production, is now described with reference to FIG. 4. In particular, FIG. 4 presents a cross sectional view of the PCSEL 20 in accordance with an embodiment of the present invention.

Unlike the PCSEL 1 of FIG. 1, PCSEL 20 comprises a p-type semiconductor substrate 21 upon which the other layers of the PCSEL 20 are formed. In the presently described embodiment, the p-type semiconductor substrate 21 comprises a 600 μm thick layer of Indium Phosphide (InP) with a Zinc dopant having a 1.6×10¹⁸ cm⁻³ carrier concentration.

A metal-organic chemical vapour deposition (MOCVD) technique is then employed to form a first p-type semiconductor layer 22 on the p-type semiconductor substrate 21. The p-type semiconductor layer 22 comprises a 0.1 μm thick layer of Indium Phosphide (InP) doped with a Zinc dopant having an 8×10¹⁷ cm⁻³ carrier concentration. The thickness and doping levels within the first p-type layer 22 are selected to allow the PCSEL 20 to generate an output field 23 at a wavelength of 1,310 nm.

There is then deposited a first layer of an n-type semiconductor material 24. In the presently described embodiment, the n-type semiconductor material 24 comprises a 0.2 μm thick layer of Indium Gallium Arsenide Phosphide (InGaAsP) with a Tin dopant having a 1.0×10¹⁸ cm⁻³ carrier concentration.

A two-dimensional array of atoms or voids 25 is then etched into the n-type semiconductor layer 24 such that this layer functions as a photonic crystal (PC) layer 24 within the PCSEL 20. In the presently described embodiment, the atoms 25 comprises triangular atoms arranged within a regular square lattice. The lattice constant (α) is set to 412 nm to match the desired wavelength (1,310 nm) of the output field 23. It will be appreciated by the skilled reader that, in alternative embodiments, the atoms 25 may comprises different regular or irregular geometric shapes (e.g. circular, oval, diamond, square or chevron shapes) and the lattice may comprise alternative regular or irregular lattice structures (e.g. triangular, hexagonal or Kagome) having different lattice constants (α).

There is then overgrown a second layer of an n-type semiconductor material 26 such that the array of atoms 25 is infilled with the second layer of n-type semiconductor material 26, thus effectively forming an n-type grating structure within the PCSEL 20. In the presently described embodiment, the n-type semiconductor material 26 comprises a 0.1 μm thick layer of Indium Phosphide (InP) with a Tin dopant having an 8.0×10¹⁷ cm⁻³ carrier concentration.

The next layer to be deposited is a third layer of an n-type semiconductor material which acts as a first cladding layer within the PCSEL 20. In the presently described embodiment, the n-type semiconductor material 27 comprises a 0.1 μm thick layer of Aluminium Gallium Indium Arsenide (Al_{[x]}GaIn_{[y]}As) with a Tin dopant having an 8.0×10¹⁷ cm⁻³ carrier concentration. The n-type semiconductor material 27 is deposited such that “x” the concentration of Aluminium varies from 0.9 to 0.72 as the layer is deposited. In the presently described embodiment “y” the concentration of Indium is set to be 0.528.

A first undoped 0.1 μm thick Aluminium Gallium Indium Arsenide (Al_{[x]}GaIn_{[y]}As) layer 28 is then grown on the first cladding layer 27, where x=0.72 and y=0.528. The refractive index of layer 28 is selected to be a lower than the layers which form the Multi-Quantum Well (MQW) active layer 29 of the PCSEL 20. As a result, layer 28 is employed as a first separate confinement heterostructure (SCH) layer within the PCSEL 20 device and thus assists with the confinement of light within the MQW active layer 29.

The next layer in the PCSEL 20 is the MQW active layer 29. The MQW active layer may comprise many different structures as known to those skilled in the art. In general, the MQW active layer 29 will comprise multiple quantum wells equally spaced between half-wave structures that allow the MQW active layer 29 to be electrically pumped by an input drive current. An example MQW active layer 29 may comprise AlGaInAs quantum wells equally spaced between half-wave AlGaInAs structures that allow the MQW active layer 29 to be electrically pumped to generate the output field 23 at 1,310 nm.

A second undoped 0.1 μm thick Aluminium Gallium Indium Arsenide (Al_{[x]}GaIn_{[y]}As) layer 30 is then grown on the MQW active layer 29, where again x=0.72 and y=0.528. The refractive index of layer 30 is selected to be a lower than the layers which form the Multi-Quantum Well (MQW) active layer 29 of the PCSEL 20. As a result, layer 30 is employed as a second separate confinement heterostructure (SCH) layer within the PCSEL device and thus assists with the confinement of light within the MQW active layer 29.

The next layer to be deposited is a fourth layer of an n-type semiconductor material which acts as a second cladding layer within the PCSEL 20. In the presently described embodiment, the n-type semiconductor material 31 comprises a 0.1 μm thick layer of Aluminium Gallium Indium Arsenide (Al_{[x]}GaIn_{[y]}As) with a Tin dopant having an 8.0×10¹⁷ cm⁻³ carrier concentration. The n-type semiconductor material 31 is deposited such that “x” the concentration of Aluminium varies from 0.72 to 0.9 as the layer is deposited. In the presently described embodiment “y” the concentration of Indium is set to be 0.528.

The final semiconductor layer the PCSEL 20 device is fifth layer of an n-type semiconductor material 32. The n-type layer 32 comprises a 1 μm thick layer of Indium Phosphide (InP) with a Tin dopant having a 1.2×10¹⁷ cm⁻³ carrier concentration. The thickness and doping levels within the n-type layer 32 are selected to allow the PCSEL to generate the output field 23 at a wavelength of 1,310 nm.

Electrical contacts 33 and 34 are located on the external surfaces the PCSEL 20. The second electrical contact 34 is in the shape of a ring, the aperture of which defines the output surface 35 of the PCSEL 20.

As a result of the above described structure, when an electrical current is provided between the first 33 and second 34 electrical contacts, the PCSEL 20 begins to lase and the output field 23 at a wavelength of 1,310 nm is emitted from the output surface 35.

PCSEL 20 is found to have around a 30% reduction in gain threshold value, a 50% improved L-I slope efficiency and higher output power than that those exhibited by the PCSEL 1 presented in FIG. 1. The primary reason for these improved operating parameters is the fact that the design of PCSEL 20 results in a shift in overlap of the normalised vertical optical mode profile between the p-type region and the n-type regions of the PCSEL 20 when compared with those presented in FIGS. 2 and 3 for the PCSEL 1 of FIG. 1. In PCSEL 20 the overlap within the n-type region of the PCSEL 20 is now around three times greater than that of the normalised vertical optical mode profile within the p-type region of the PCSEL 20. When combined with the known lower free carrier cross sectional losses, the overall result is a PCSEL 20 that exhibits a lower internal loss (αᵢ) value and thus the above-mentioned improved operating parameters.

The new PCSEL 20 design, and associated improved operating parameters, have been made possible because the applicants have chosen to base their PCSEL structure on a p-type semiconductor substrate 21. This is contrary to the traditional starting point within the field of semiconductor laser devices where n-type semiconductor substrates are normally employed for the reasons described above i.e. n-type semiconductor substrates exhibit lower free carrier cross sectional losses, lower defect densities and are less prone to surface segregation than corresponding p-type semiconductor substrates.

A further factor contributing to the improved operating parameters of the PCSEL 20 is the fact that the structure comprises graded cladding layers 27 and 31. The incorporation of these graded cladding layers 27 and 31 is found to provide for better electrical conduction through the PCSEL 20 and for better optical confinement within the MQW active layer when compared with a device that incorporates non-graded cladding layers. The reason for this resides in the fact that the graded cladding layers 27 and 31 provide for a corresponding graded change in refractive index across the PCSEL 20 as compared with a stepwise change that would be associated with non-graded cladding layers.

A further advantage of the design of the PCSEL 20 is the fact that the a photonic crystal (PC) layer 24 is formed within the PCSEL 20 before the MQW active layer 29 is deposited. With this arrangement, the risk of damaging the MQW active layer 29 when etching the two-dimensional array of atoms or voids 25 is removed. As a result, the PCSEL 20 is found to provide better quality output field 23 and exhibit higher reliability than some of the alternative embodiments described below.

One such alternative embodiment involves replacing one or more of the n-type semiconductor layers 24, 26 and 27 of the PCSEL 20 with a corresponding p-type semiconductor layers.

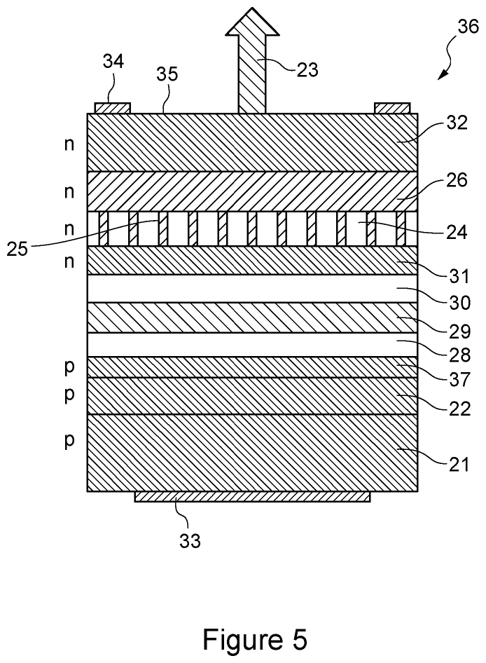

A further alternative embodiment is the PCSEL 36 presented in FIG. 5. In particular, FIG. 5 presents a cross sectional view of the PCSEL 36. Like parts of PCSEL 36 within FIG. 5 are marked with the same reference numerals employed within FIG. 4 for PCSEL 20.

PCSEL 36 again comprises a p-type semiconductor substrate 21 upon which the other layers of the PCSEL 36 are formed. In the presently described embodiment, a metal-organic chemical vapour deposition (MOCVD) technique is then employed to form the other layers of the PCSEL 36.

The first layer is a first p-type semiconductor layer 22. The thickness and doping levels within the first p-type semiconductor layer 22 are selected to allow the PCSEL 36 to generate an output field 23 at a desired wavelength e.g. 1,310 nm.

There then follows a second layer of a p-type semiconductor material 37 which acts as a first cladding layer within the PCSEL 36. In the presently described embodiment, the p-type semiconductor material 37 comprises a 0.1 μm thick layer of Aluminium Gallium Indium Arsenide (Al_{[x]}GaIn_{[y]}As) with a with a Zinc dopant having an 8.0×10¹⁷ cm⁻³ carrier concentration. The p-type semiconductor material 37 is deposited such that “x” the concentration of Aluminium varies from 0.9 to 0.72 as the layer is deposited. In the presently described embodiment “y” the concentration of Indium is set to be 0.528.

The first undoped Aluminium Gallium Indium Arsenide (Al_{[x]}GaIn_{[y]}As) layer 28 is then grown on the first cladding layer 37, where x=0.72 and y=0.528. The next layer in the PCSEL 36 is the MQW active layer 29. This is then followed by the second undoped Aluminium Gallium Indium Arsenide (Al_{[x]}GaIn_{[y]}As) layer 30. Within undoped layers and 30, x=0.72 and y=0.528 and their refractive indices are again selected to be a lower than the layers which form the Multi-Quantum Well (MQW) active layer 29 of the PCSEL 36. As a result, layers 28 and 30 again function as first and second separate confinement heterostructure (SCH) layers within the PCSEL 36.

The next layer to be deposited is the first layer of an n-type semiconductor material which acts as a second cladding layer within the PCSEL 36.

The photonic crystal (PC) layer 24 is then formed, as described above, before being overgrown with the layer of an n-type semiconductor material 26 such that the array of atoms 25 is again infilled with the layer of n-type semiconductor material 26.

The final semiconductor layer of the PCSEL 36 device is the layer of an n-type semiconductor material 32. The thickness and doping levels within the n-type layer 32 are again selected to allow the PCSEL 36 to generate output field 23 at the desired wavelength.

Electrical contacts 33 and 34 are again located on the external surfaces the PCSEL 36. The second electrical contact 34 is in the shape of a ring, the aperture of which defines the output surface 35 of the PCSEL 36. As a result of the above described structure, when an electrical current is provided between the first 33 and second 34 electrical contacts, the PCSEL 36 begins to lase and an output field 23, at a wavelength of 1,310 nm, is emitted from the output surface 35.

As can be seen, the main difference between the PCSEL 20 and PCSEL 36 is that the location of the photonic crystal (PC) layer 24 and the Multi-Quantum Well (MQW) active layer 29 have been swapped.

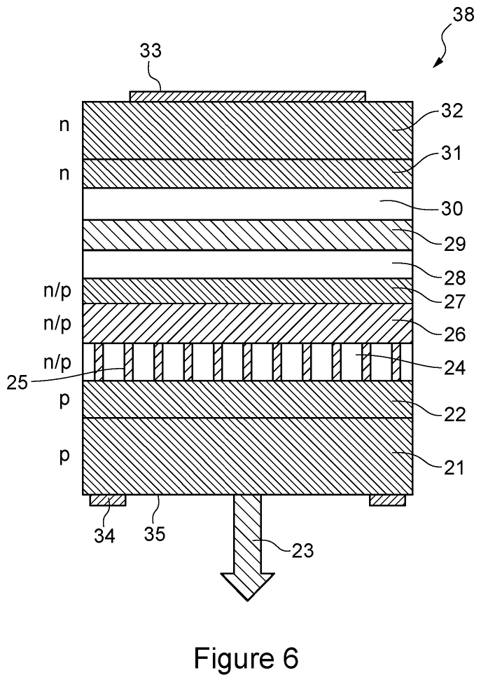

A further alternative embodiment of the PCSEL 20 of FIG. 4 is the PCSEL 38 presented in FIG. 6. In particular, FIG. 6 presents a cross sectional view of the PCSEL 38. Like parts of PCSEL 36 within FIG. 6 are marked with the same reference numerals employed within FIG. 4 for PCSEL 20. The main difference between PCSEL 38 and PCSEL 20 is the fact that the location of the electrical contacts 33 and 34 on the external surfaces the PCSEL 38 are reversed when compared with PCSEL 20. As a result, the output surface 35 from which the output field 23 is generated is the surface of p-type semiconductor substrate 21 opposite to which the remaining layers of the device are formed.

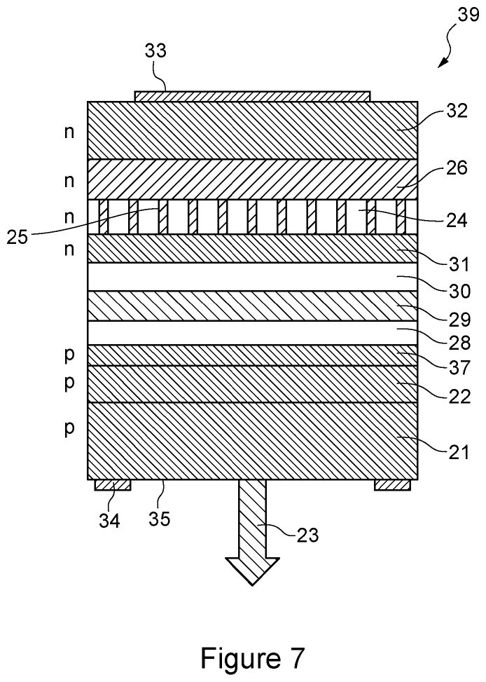

In a similar manner, an alternative embodiment of the PCSEL 36 of FIG. 5 is the PCSEL 39 presented in FIG. 7. In particular, FIG. 7 presents a cross sectional view of the PCSEL 39. Like parts of PCSEL 39 within FIG. 7 are marked with the same reference numerals employed within FIG. 5 for PCSEL 36. The main difference between PCSEL and PCSEL 36 is the fact that the location of the electrical contacts 33 and 34 on the external surfaces the PCSEL 39 are reversed when compared with PCSEL 36. As a result, the output surface 35 from which the output field 23 is generated is the surface of p-type semiconductor substrate 21 opposite to which the remaining layers of the device are formed.

As will be appreciated by the skilled reader, the semiconductor materials and dopants employed within the PCSELs 20, 36, 38 and 39 may comprise alternative materials to those described above. For example, the p-type semiconductor substrate 21 may comprise Gallium Arsenide (GaAs). The dopant material within any of the p-type semiconductor material layers may alternatively comprise Beryllium. In a similar manner, the dopant material within any of the n-type semiconductor material layers may alternatively comprise Sulphur or Indium.

In each of the PCSELs 20, 36, 38 and 39 described above the overgrown n-type semiconductor layer 26 may be omitted. Within these embodiments the atoms 10 are air filled rather than being infilled with n-type semiconductor material 26.

It will also be appreciated by the skilled reader that the Multi-Quantum Well (MQW) active layer 29 and the photonic crystal (PC) layer 24 may take alternative forms in order to change the operating wavelength of the PCSELs 20, 36, 38 and 39.

A surface emitting laser device and a method for manufacturing is disclosed. The surface emitting laser device comprises a semiconductor substrate on which are located a photonic crystal (PC) structure comprising a bulk medium having a first refractive index and an array of scattering centres located within the bulk medium, the scattering centres having a second refractive index different to the first refractive index; and an active layer, optically coupled to the photonic crystal structure. The semiconductor substrate comprises a p-type semiconductor substrate. The described surface emitting laser device is found to exhibit lower gain threshold values, improved L-I slope efficiency and higher output powers than that those known in the art which are formed on a p-type semiconductor substrate.

Throughout the specification, unless the context demands otherwise, the term “comprise” or “include”, or variations such as “comprises” or “comprising”, “includes” or “including” will be understood to imply the inclusion of a stated integer or group of integers, but not the exclusion of any other integer or group of integers.

Furthermore, reference to any prior art in the description should not be taken as an indication that the prior art forms part of the common general knowledge.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims.

1. A photonic crystal surface emitting laser (PCSEL) device comprising:
a p-type semiconductor substrate on which are deposited:
a photonic crystal structure comprising a bulk medium having a first refractive index and an array of scattering centres located within the bulk medium, the scattering centres having a second refractive index different to the first refractive index;
an active layer, optically coupled to the photonic crystal structure; and
an n-type semiconductor layer, the n-type semiconductor layer being deposited on the p-type semiconductor substrate after the photonic crystal structure and active layer are deposited, wherein an overlap of a normalised vertical optical mode within an n-type semiconductor region of the PCSEL is greater than within a p-type semiconductor region of the PCSEL.

2. A photonic crystal surface emitting laser (PCSEL) device as claimed in claim 1 wherein the photonic crystal structure is deposited between the active layer and the p-type semiconductor substrate.

3. A photonic crystal surface emitting laser (PCSEL) device as claimed in claim 1 wherein the bulk medium comprises a first n-type semiconductor material.

4. A photonic crystal surface emitting laser (PCSEL) device as claimed in claim 1 wherein the scattering centres comprise voids formed within the bulk medium.

5. A photonic crystal surface emitting laser (PCSEL) device as claimed in claim 4 wherein the voids are infilled with a second n-type semiconductor material.

6. A photonic crystal surface emitting laser (PCSEL) device as claimed in claim 1 wherein the surface emitting laser device further comprises a p-type semiconductor layer deposited between the active layer and the p-type semiconductor substrate.

7. A photonic crystal surface emitting laser (PCSEL) device as claimed in claim 6 wherein the photonic crystal surface emitting laser (PCSEL) device further comprises an n-type semiconductor layer deposited on the opposite side of the active layer to that of the p-type semiconductor layer.

8. A photonic crystal surface emitting laser (PCSEL) device as claimed in claim 1 wherein the photonic crystal surface emitting laser (PCSEL) device further comprises first and second cladding layers deposited on opposite sides of the active layer.

9. A photonic crystal surface emitting laser (PCSEL) device as claimed in claim 8 wherein the first and second cladding layers comprise first and second graded cladding layers.

10. A photonic crystal surface emitting laser (PCSEL) device as claimed in claim 8 wherein the photonic crystal surface emitting laser (PCSEL) device further comprises a first separate confinement heterostructure (SCH) layer located between the first cladding layer and the active layer.

11. A photonic crystal surface emitting laser (PCSEL) device as claimed in claim 8 wherein the photonic crystal surface emitting laser (PCSEL) device further comprises a second separate confinement heterostructure (SCH) layer located between the second cladding layer and the active layer.

12. A photonic crystal surface emitting laser (PCSEL) device as claimed in claim 1 wherein the photonic crystal surface emitting laser (PCSEL) device further comprises a first and second electrical contacts located on opposite external surfaces of the device.

13. A photonic crystal surface emitting laser (PCSEL) device as claimed in claim 12 wherein the first or second electrical contacts comprise an aperture which defines the output surface of the photonic crystal surface emitting laser (PCSEL) device.

14. A method of manufacturing a photonic crystal surface emitting laser (PCSEL) device comprising a p-type semiconductor substrate, the method comprising depositing on the p-type semiconductor substrate:
a photonic crystal structure comprising a bulk medium having a first refractive index and an array of scattering centres located within the bulk medium, the scattering centres having a second refractive index different to the first refractive index;
an active layer, optically coupled to the photonic crystal structure; and
an n type semiconductor layer, the n-type semiconductor layer being deposited on the p-type semiconductor substrate after the photonic crystal structure and active layer are deposited, wherein an overlap of a normalised vertical optical mode within an n-type semiconductor region of the PCSEL is greater than within a p-type semiconductor region of the PCSEL.

15. A method of manufacturing a photonic crystal surface emitting laser (PCSEL) device as claimed in claim 14 wherein the photonic crystal structure is deposited on the p-type semiconductor substrate before the active layer.

16. A method of manufacturing a photonic crystal surface emitting laser (PCSEL) device as claimed in claim 14 wherein depositing the photonic crystal on the p-type semiconductor substrate comprises depositing a layer of a first n-type semiconductor material to form the bulk medium.

17. A method of manufacturing a photonic crystal surface emitting laser (PCSEL) device as claimed in claim 14 wherein depositing the photonic crystal on the p-type semiconductor substrate further comprises etching a plurality of voids within the layer of the first n-type semiconductor material to form the array of scattering centres.

18. A method of manufacturing a photonic crystal surface emitting laser (PCSEL) device as claimed in claim 17 wherein depositing the photonic crystal on the p-type semiconductor substrate further comprises depositing a layer of a second n-type semiconductor material to infill the plurality of atoms or voids.

19. A method of manufacturing a photonic crystal surface emitting laser (PCSEL) device as claimed in claim 14 wherein the method further comprises depositing a p-type semiconductor layer between the active layer and the p-type semiconductor substrate.

20. A method of manufacturing a photonic crystal surface emitting laser (PCSEL) device as claimed in claim 19 wherein the method further comprises depositing an n-type semiconductor layer located on the opposite side of the active layer to that of the p-type semiconductor layer.

21. A method of manufacturing a photonic crystal surface emitting laser (PCSEL) device as claimed in claim 14 wherein the method further comprises forming first and second graded cladding layers located on opposite sides of the active layer.

22. A method of manufacturing a photonic crystal surface emitting laser (PCSEL) device as claimed in claim 21 wherein the method further comprises forming a first separate confinement heterostructure (SCH) layer located between the first cladding layer and the active layer.

23. A method of manufacturing a photonic crystal surface emitting laser (PCSEL) device as claimed in claim 21 wherein the method further comprises forming a second separate confinement heterostructure (SCH) layer located between the second cladding layer and the active layer.

24. A method of manufacturing a photonic crystal surface emitting laser (PCSEL) device as claimed in claim 14 wherein the method further comprises providing a first and a second electrical contact located on opposite external surfaces of the device.

25. A method of manufacturing a photonic crystal surface emitting laser (PCSEL) device as claimed in claim 24 wherein providing the first and second electrical contacts comprises providing an aperture within the first or second electrical contacts to define an output surface of the surface emitting laser device.
